(19) United States
(12) Patent Application Publication
(10) Pub. No.: US 2003/0106988 A1
(43) Pub. Date: Jun. 12, 2003

(54) Optical beam sampling monitor

(76) Inventor: John Severn, Totnes (GB)

Correspondence Address: William M. Lee, Jr., Lee, Mann, Smith, McWilliams, Sweeney & Ohlson, P. O. Box 2786, Chicago, IL, 60690-2786, US

(21) Appl. No.: 10/006,509

(22) Filed: Dec. 6, 2001

(51) Int. Cl. H01L 31/00

(52) U.S. Cl. 250/214.1

(57) ABSTRACT

A photo-detector device is arranged for in-beam monitoring of a light beam. The device absorbs a proportion of the energy of the beam whilst allowing the remainder of the energy of the beam to pass through. In this way, a sampling mirror and photo-detector arrangement can be replaced with a photo-detector which provides within its own structure the sampling function. There are a number of applications where in-line sampling is required, and the invention can be used in many such applications.

### FIELD OF THE INVENTION

The invention relates to a method and apparatus for monitoring the power of an optical beam and a system incorporating this apparatus.

### BACKGROUND OF THE INVENTION

Power monitoring of optical signals is required in many different applications.

One common way to monitor power, or to carry out other optical signal analysis, is to tap a small proportion of the signal power (for example 4%) and pass this optical power to a monitoring photodiode or other analytical equipment. The tapping is carried out by Y-couplers or beam splitters. Each of these requires space in the package and additional components.

One particular application where power monitoring is required is at the output of a laser device which generates an optical signal for transmission in an optical communications system. This power measurement may then be used as a feedback signal for controlling the optical power launched into a fiber, as this power may need to be tailored to other equipment in the system, such as optical receivers.

For monitoring laser output power, front or rear facet monitors are widely used. In a rear facet monitor, one of the reflective surfaces of the laser cavity is made slightly transparent, and a diode detector is placed against the slightly transparent face. The power “escaping” from the laser cavity through this surface can be used to derive the optical output power of the laser. Although this arrangement does not require an additional splitter or coupler, in many cases, there is not sufficient space behind the laser transmitter.

In a front facet monitor, a proportion of the output power is tapped off, and the tapped signal is provided to a monitoring photodiode. This requires the additional beam splitter or coupler.

### SUMMARY OF THE INVENTION

According to the invention, there is provided a photo-detector device for in-beam monitoring of a light beam, the device absorbing a proportion of the energy of the beam whilst allowing the remainder of the energy of the beam to pass through.

The invention enables a sampling mirror and photo-detector arrangement to be replaced with a photo-detector which provides within its own structure the sampling function. There are a number of applications where in-line sampling is required, and the invention can be used in many such applications.

The photodetector preferably comprises an absorbing layer which produces an output signal dependent on the intensity of the light beam incident upon the device. This may define a photodiode or photoconductor structure.

The absorbing layer may comprise InGaAsP, and in the case of a photodiode structure, a diffused p-type region is provided in the absorbing layer. The absorbing layer is preferably provided over a substrate arrangement. The contacts may be on opposite sides of the substrate or on the same side. In either case, the contacts are designed to allow the passage of light through, for example being provided with a window.

Modifications may be made to the substrate, for guiding or focusing the sampled radiation. For example, a doped region may be provided passing through the substrate for confinement of the signal beam passing through the substrate. Alternatively, a doped region may be provided in one side of the substrate opposite the absorbing layer for focusing the light beam exiting the substrate.

In one embodiment, a well is provided in the absorbing layer, and wherein a diffused p-type region is provided in the side walls of the well for absorbing a peripheral edge of the light beam. This avoids the need to ensure high transparency of the absorbing layer, as there is instead provided a region with no absorbing layer through which most of the light beam energy is directed.

The device may be used in a fiber power monitor or in an optical transmitter unit.

The invention also provides a method of monitoring the intensity of a light beam, comprising:

absorbing a proportion of the energy of the beat using a device positioned in-line with the beam;

using the absorbed light to determine the intensity of the light beam; and

allowing the remainder of the energy of the beam to pass through the device.

In one embodiment, absorbing a proportion of the energy comprises absorbing a periphery of the light beam and allowing a central region of the light beam to pass substantially unattenuated.

### BRIEF DESCRIPTION OF THE DRAWINGS

Examples of the invention will now be described in detail with reference to the accompanying drawings, in which:

FIG. 1 shows a first example of monitoring device of the invention:

FIG. 2 shows the mounting of the device of FIG. 1 on a circuit board;

FIG. 3 shows a second example of monitoring device of the invention;

FIG. 4 shows the mounting of the device of FIG. 3 on a circuit board;

FIG. 5 shows a third example of monitoring device of the invention;

FIG. 6 shows a fourth example of monitoring device of the invention;

FIG. 7 shows a fifth example of monitoring device of the invention;

FIG. 8 shows a sixth example of monitoring device of the invention;

FIG. 9 shows use of the device for monitoring output power of a transmitter; and

FIG. 10 shows inline fiber mounting of the device.

In the Figures, the same reference numerals are used in different Figures for the same parts.

### DETAILED DESCRIPTION

The invention provides a device for in-beam monitoring of a light beam, in which most of the energy of the beam can pass through the device, and a proportion of the energy is absorbed for monitoring.

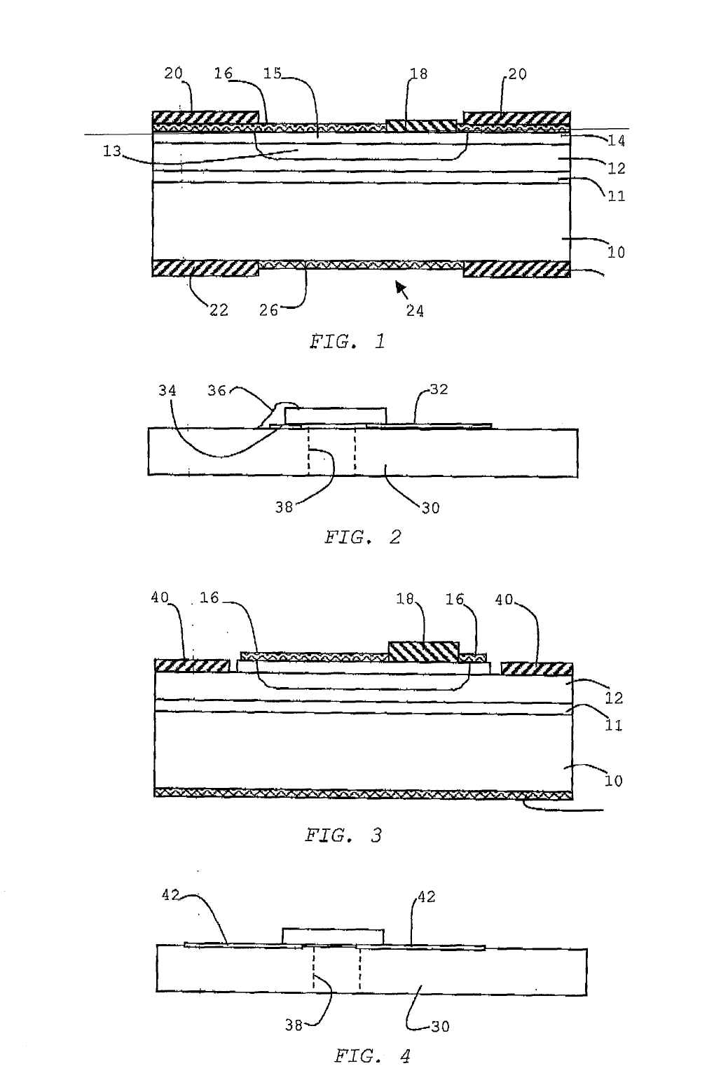

A first example of the device of the invention is shown in FIG. 1. The device comprises a tin-doped InP substrate 10, which is electrically conductive and optically transparent at the wavelength of interest. The device may be for monitoring DWDM signals) around 1550 nm wavelength) or for the 1310 nm window used for single channel applications.

On the substrate are epitaxially grown an n-type InP butter layer 11, and an intrinsic InGaAs absorption layer 12, which is intrinsically n-type. A diffused p-type region 13 is provided which creates the p-n photodiode junction. An InP capping layer 14 overlies the absorption layer 12. A portion 15 of the capping layer is converted into p-type material together with the region 13, and this may for example be through the diffusion of zinc from a source of ZnAs.

An antireflection layer 16 is provided over the capping layer 15, and a top contact 18 in the form of a bond pad is formed in a window in the layer 16, for contacting the p-type region 15.

Optional metallic mask regions 20 are provided for shielding the absorption layer 12, other than the p-n junction area, from the incident light, which enters from above in FIG. 1.

The bond pad 18 defines one contact for the p-n junction diode, and the other contact is defined by contact metal areas 22 on the opposite side of the substrate 10. These contact areas leave a window 24 through which light of the wavelength of interest can pass. The window 24 may be provided with an antireflection coating 26.

The device of FIG. 1 is designed substantially to allow the passage of light through the device, and only a small proportion of the light energy is absorbed, for example 5%.

The device can be made substantially transparent in two ways. One possibility is to provide the diode with a very thin absorbing layer 12, so that the region becomes transparent to radiation. Calculations show that if this region is to absorb 5% of the incident radiation it needs to be about 100 Angstroms thick, significantly shorter than the absorption length of the radiation to be sampled. Such thin layers can be grown using MOCVD.

The manufacture of the diode requires that the p-type region 13 be diffused into the structure to a depth such that the p-n boundary lies within the absorbing layer 12. This may be difficult if the absorbing layer 12 is very thin. However, recent advances in APD manufacture where very accurate diffusion is required make this diffusion depth tolerance achievable.

The accurate diffusion is probably the most complicated aspect of the manufacture and there are alternative designs which avoid the need for this process accuracy.

A first possibility is to change the composition of the absorption layer 12 to change the wavelength at which the layer absorbs. By shifting the absorption wavelength so that the wavelength of interest is on the edge of the absorption band of the material, the layer can be made substantially transparent to the wavelength of interest whilst absorbing sufficient light for the monitoring function.

For example, the absorbing layer may be expressed as:

In(1-x)G(x)As(y)P(1-y).

In order to change the wavelength characteristics, the ratio of As to P is varied. For example x=0.15 and y=0.33 enable operation at 1000 nm, x=0.15 and y=0.45 enable operation for the 1310 nm window and x=0.15 and y=0.55 enable operation at 1550 nm.

FIG. 1 shows the simplest form of the diode structure, in which the electrical contacts are arranged one each side of the substrate 10. This could be mounted and connected to a substrate as shown in FIG. 2. The substrate 30 comprises a ceramic submount for the photodiode, and has areas 32 and 34 for contact with the contact areas 22. A wire bond 36 makes contact with the top contact 18.

A via 38 is provided through the substrate for the passage of light.

An alternative method for providing the n-side substrate contact is to etch away the capping layers in a defined region and then contact the substrate on the same side as the p side top contact. This diode structure is shown in FIG. 3 and the mounting arrangement in FIG. 4. In this case, the n-type contacts 40 are provided directly over the absorbing layer 12, as shown. The n-type and p-type contacts are then on the same side of the substrate, and connect to respective areas 42 on the substrate 30, as shown. Although not shown in FIG. 3, the layer thicknesses may be selected so that the top surfaces of the contacts 18, 40 are coplanar.

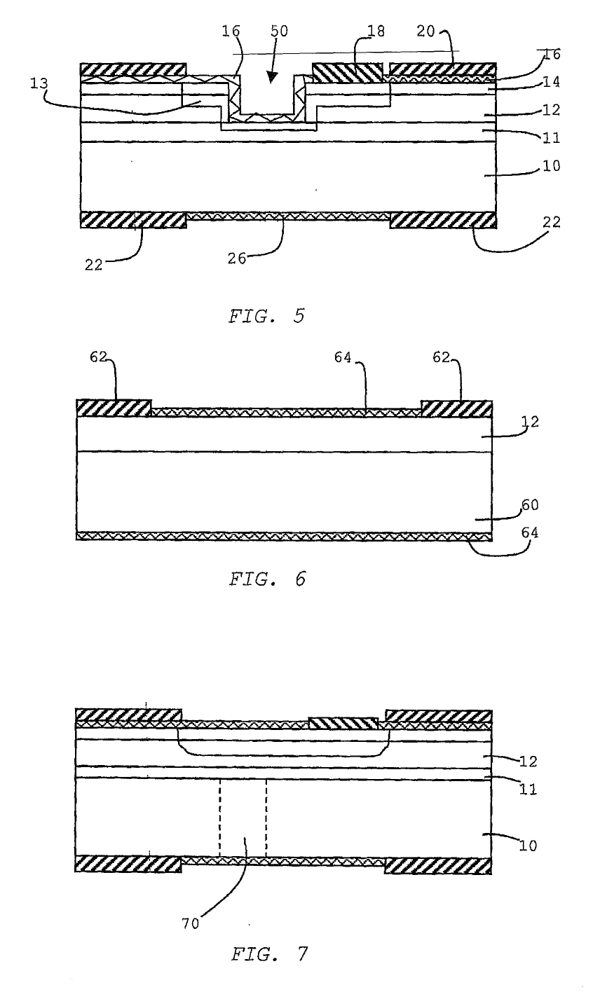

As mentioned above, one possible way to overcome the need for a very thin absorption layer is to select appropriately the composition of the material. An alternative is to provide a differently shaped absorption region. In the example of FIG. 5, a well 50 is provided in the absorbing layer. The well 50 defines a window in the absorption layer 12 through which light can pass unattenuated (regardless of the thickness of the absorption layer). The diffused p-type region 13 within the absorbing layer extends into the side walls of the well 50, and as a result peripheral light contributes to the generation of carriers at the p-n junction, whereas central light passes through the window.

The diffusion region 13 is of a standard thickness but only resides within an annular region of the window through which the light passes. The annular region can be processed by selective epitaxial growth. The annular absorbing region thus samples the edge of the light beam, absorbing 100% of these peripheral rays whereas the centre of the window contains no absorbing material allowing the light to pass through without attenuation.

This alternative photodiode design may be easier to process especially the diffusion process. However, the diameter of the annulus does need to be matched to the diameter of the optical beam, and during assembly of the photodiode into the optical component it will need to be aligned more accurately than the photodiode with thin adsorbing layer. Both of these steps are easily achieved.

All photo-detectors currently used in telecommunications applications are photo-diodes. However, photoconductor devices can also be used for optical signal monitoring. Photoconductors do not contain a diffused p-type region, therefore avoiding this accurate process step. A photo-conductor can be made with a large active area so it does not need to be aligned accurately. The photoconductor device of FIG. 6 comprises a thin semi-transparent absorbing layer of InGaAsP 12 on a high resistivity Fe doped InP substrate 60. A metal contact pad 62 is provided at each end of the photo-conductive strip, and antireflection coatings 64 are provided on each face of the device.

As the light passes through the InP substrate it is possible to confine or focus the beam by implanting additional features within the substrate. These features can be made by selectively doping regions of the substrate thereby locally changing the refractive index of the medium

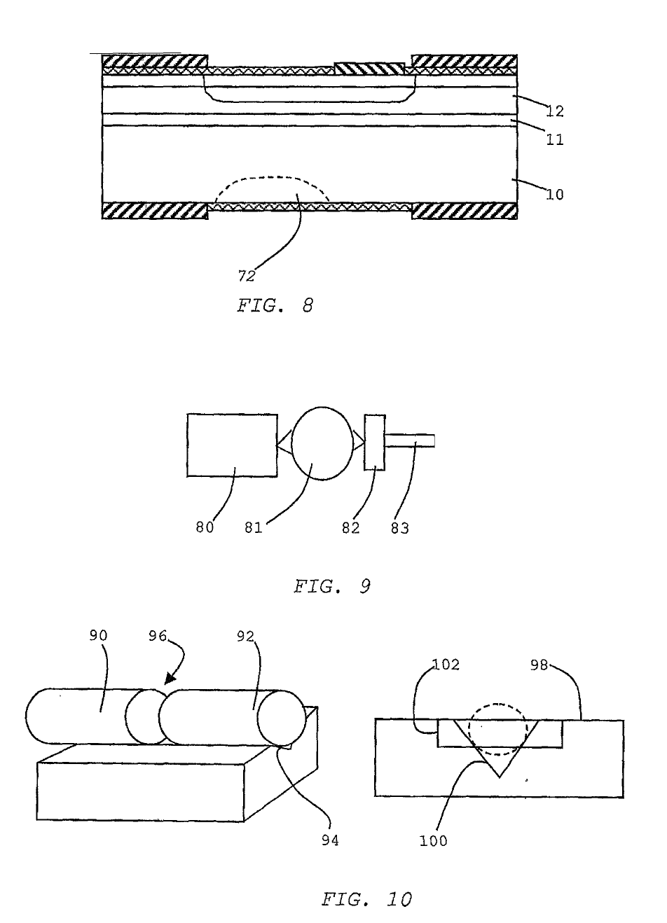

FIGS. 7 and 8 show modifications to the basic design of FIG. 1. It will be appreciated that the modifications may be applied to all other designs. In FIG. 7, a waveguide function is shown by providing a rod 70 of higher refractive index material. In FIG. 8, a lens function is implemented using a shaped region 72 of higher refractive index material.

These features of course require alignment of the photo-detector to the light beam to be sampled.

The photo-detector of the invention can be used in various applications. One application is to monitor the front facet radiation from a laser diode. Front facet monitoring is useful in a number of instances such as:

where VCSEL (Vertical Cavity Surface Emitting Lasers) are employed which provide no rear facet emission, optical power monitoring must be done using the radiation from the front (top) surface;

where an edge emitting laser has a 100% reflective coating on the rear facet to minimize rear end losses; and

where the RF connection to an edge emitting laser blocks the emission from the rear facet and prevents a clear optical path onto a monitoring photo-detector. In the past, the RF signal energy has been fed to the laser diode from the side (at right angles to the optical signal). However, at data rates of 10 Gbit/s and above the RF signal does not traverse corners easily. The trend towards smaller optical interfaces designed to provide very close packing density has also recently resulted in the laser diode drive circuitry being moved to the rear of the optical interface module and the RF signal is introduced from the rear.

There are other methods of front facet monitoring using a beam splitter or waveguide coupler, the advantage of this idea is smaller size and lower cost.

There are numerous ways in which a front facet monitor may be implemented, FIG. 9 shows schematically a transmitter 80 and the monitoring device 82. The transmitter output is focused by a lens 81 onto the device 82, which is provided with a fiber output 83.

An alternative application of the device of the invention is for monitoring optical signals carried in optical fibers. This use of the sampling photodiode is shown in FIG. 10. The arrangement shown comprises an input fibre 90 and an output fibre 92 aligned in a v-groove 94. There is a small gap 96, for example of about 0.15 mm between the ends of the two fibres. The sampling photo-detector is mounted on a separate substrate 98, which also has a v-groove 100. This substrate 98 sits over the input fibre 90 like a saddle, and the photo-detector 102, which is mounted on the end face of the substrate, is suspended in the gap between the two fibres 90, 92. Electrical contacts are bought out over the top of the substrate 98.

Various possible designs for the device of the invention have been described, although it will be understood by those skilled in the art that there are various alternative designs and that numerous modifications may be made to the described designs.

We claim:

1. A photo-detector device for in-beam monitoring of a light beam, the device absorbing a proportion of the energy of the beam whilst allowing the remainder of the energy of the beam to pass through.

2. A photodetector device according to claim 1 comprising a photodiode.

3. A photodetector device according to claim 1, in which the photodetector comprises an absorbing layer which produces an output signal dependent on the intensity of the light beam passing through the device.

4. A photodetector device according to claim 3, in which the absorbing layer comprises InGaAsP.

5. A photodetector device according to claim 4, wherein a diffused p-type region is provided in the absorbing layer.

6. A photodetector device according to claim 3, wherein the absorbing layer is provided over a substrate arrangement, and wherein one contact for the device is provided on one side of the substrate opposite the absorbing layer, and another contact for the device is provided over the absorbing layer.

7. A photodetector device according to claim 6, wherein a window is provided in the one contact for the passage of light.

8. A photodetector device according to claim 3, wherein the absorbing layer is provided over a substrate arrangement, and wherein first and second contacts for the device are provided over the absorbing layer.

9. A photodetector device according to claim 4, wherein a well is provided in the absorbing layer, and wherein a diffused p-type region is provided in the side walls of the well for absorbing a peripheral edge of the light beam.

10. A photodetector device according to claim 3, wherein the absorbing layer is provided over a substrate arrangement, and a doped region is provided passing through the substrate for confinement of the signal beam passing through the substrate.

11. A photodetector device according to claim 3, wherein the absorbing layer is provided over a substrate arrangement, and a doped region is provided in one side of the substrate opposite the absorbing layer for focusing the light beam exiting the substrate.

12. A photodetector device according to claim 1 comprising a photoconductor.

13. A fiber power monitor comprising a photodetector device according to claim 1.

14. An optical transmitter unit comprising a photodetector device according to claim 1 for monitoring the transmitter output power.

14. A method of monitoring the intensity of a light beam, comprising:
absorbing a proportion of the energy of the beam using a device positioned in-line with the beam;
using the absorbed light to determine the intensity of the light beam; and
allowing the remainder of the energy of the beam to pass through the device.

15. A method according to claim 14, wherein absorbing a proportion of the energy comprises absorbing a periphery of the light beam and allowing a central region of the light beam to pass substantially unattenuated.
